(19) United States
(12) Patent Application Publication
(10) Pub. No.: US 2009/0256245 A1
(43) Pub. Date: Oct. 15, 2009

(54) Stacked Micro-Module Packages, Systems Using the Same, and Methods of Making the Same

(76) Inventors: Yong Liu, Scarborough, ME (US); Qiuxiao Qian, Suzhou (CN); Yumin Liu, Suzhou (CN); Zhongfa Yuan, Suzhou (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/102,799

(22) Filed: Apr. 14, 2008

(51) Int. Cl. H01L 23/495; H01L 21/60

(52) U.S. Cl. 257/666; 438/123; 257/E23.031; 257/E21.51

(57) ABSTRACT

Semiconductor die packages, methods of making said packages, and systems using said packages are disclosed. An exemplary package comprising at least one semiconductor die disposed on one surface of a leadframe and electrically coupled to at least one conductive region of the leadframe, and at least one passive electrical component disposed on the other surface of a leadframe and electrically coupled to at least one conductive region of the leadframe.

### CROSS-REFERENCES TO RELATED APPLICATIONS

NOT APPLICABLE

### BACKGROUND OF THE INVENTION

Semiconductor die packages are currently used in power supplies for computers. Because these die packages dissipate large amounts of heat for these applications, one semiconductor device is generally provided in each package so as to allow for a dedicated heat sink for each device. A recent trend in the industry has been to use a system of distributed power supplies in computers, server systems, and other electronic devices and the like. Instead of using a single power converter to supply power to all the components of a system, such distributed power supplies use several smaller buck converters to supply power to respective components of the system. In the distributed buck converter configuration, the input AC or DC power can be converted by a converter to an intermediate DC voltage that is unregulated, or lightly-regulated, typically in the range of 1 to 15 volts, and a plurality of distributed DC-to-DC buck converters convert the intermediate DC voltage to regulated levels in the range of ±1 volts to ±12 volts for specific components of the system. When converting from line power, this configuration enables the control feedback control loop of an AC-to-DC converter to be optimized for good power-factor-correction (PFC) performance since it does not have to precisely control the final output voltages to the components. When converting from DC battery power, the configuration enables non-standard battery voltages, such as Lithium ion batteries, to be readily used. The configuration also enables the buck converters to better isolate the current demands of the system's components from one another. While this configuration has many advantages, it has a disadvantage of requiring additional components and additional board space. For example, each buck converter comprises a control chip, two switching transistors, an inductor, and at least one capacitor, each of which are typically assembled together on an area of an electronic circuit board.

### BRIEF SUMMARY OF THE INVENTION

As part of making their invention, the inventors have discovered that board area required for a power converter can be significantly decreased by incorporating the components of the power converter into a single package, with the die of the control chip disposed on one surface of a leadframe and the passive components (e.g., inductor and capacitor(s)) disposed on the other surface, and with the leadframe interconnecting the die and components. The inventors have further discovered that this construction can be applied to other types of circuits comprising semiconductor dice and passive components.

Accordingly, a first general embodiment of the invention is directed to a semiconductor die package broadly comprising at least one semiconductor die disposed on one surface of a leadframe and electrically coupled to at least one conductive region of the leadframe, and at least one passive electrical component disposed on the other surface of a leadframe and electrically coupled to at least one conductive region of the leadframe.

Another general embodiment of the invention is directed to a method of manufacturing a semiconductor die package broadly comprising assembling at least one semiconductor die onto one surface of a leadframe with a conductive region of the die electrically coupled to at least one conductive region of the leadframe, and assembling at least one passive electrical component on the other surface of a leadframe with a conductive region of the die electrically coupled to at least one conductive region of the leadframe.

The present invention also encompasses systems that include packages according to the present invention, each such system having an interconnect substrate and a semiconductor die package according to the present invention attached to the interconnect substrate, with electrical connections made therewith.

The invention enables the manufacture of ultra-miniature buck converters and other circuits on the order by 2 mm by 2 mm, which can be used in portable consumer products, such as cell phones, MP3 players, PDA's, and the like.

The above general embodiments and other embodiments of the invention are described in the Detailed Description with reference to the Figures. In the Figures, like numerals may reference like elements and descriptions of some elements may not be repeated.

### BRIEF DESCRIPTION OF THE DRAWINGS

FIG. 1 shows a schematic diagram of a switching power supply that may be incorporated into a package according to the present invention.

FIG. 2 shows a perspective view of a first exemplary semiconductor die package according to the invention.

FIGS. 3-7 show perspective views of the first exemplary semiconductor die package during exemplary stages of a manufacturing process according to the invention.

FIG. 8 shows a perspective view of a second exemplary semiconductor die package according to the invention.

FIG. 9 shows a perspective view of a third exemplary semiconductor die package according to the invention.

FIGS. 10-12 show perspective views of the third exemplary semiconductor die package during exemplary stages of a manufacturing process according to the invention.

FIG. 13 shows a perspective view of a semiconductor die package attached to an interconnect substrate of a system according to the present invention.

### DETAILED DESCRIPTION OF THE INVENTION

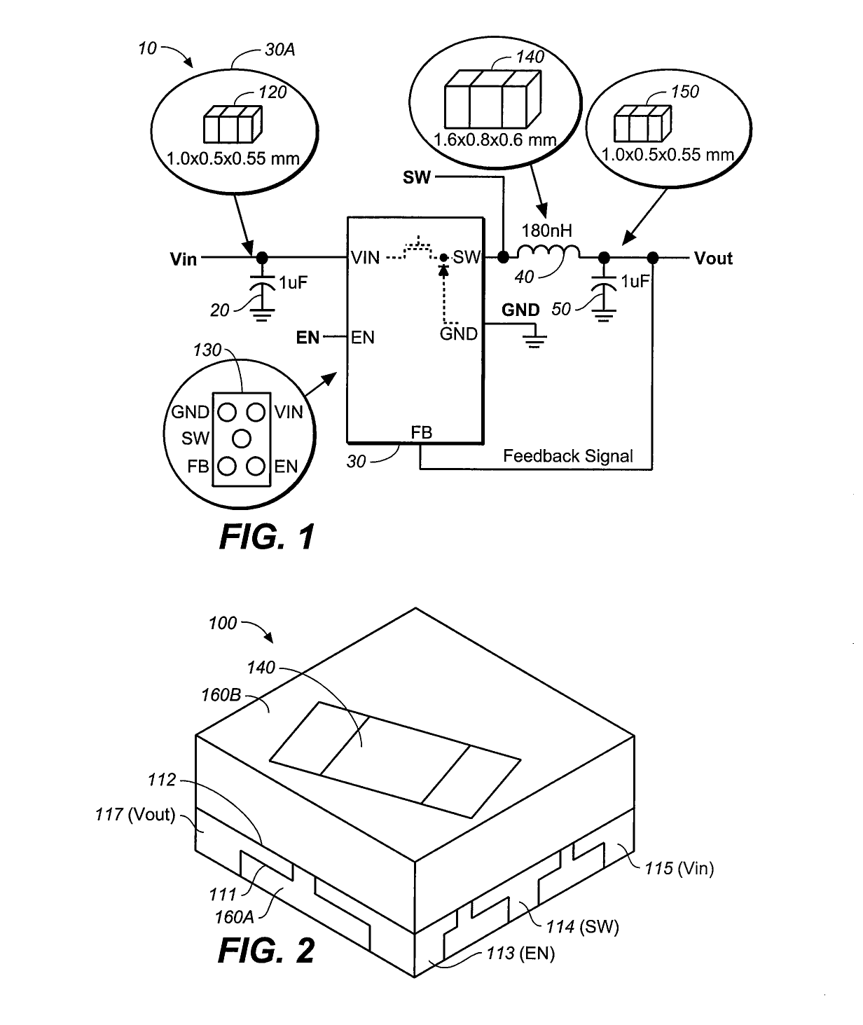

FIG. 1 shows a schematic diagram of a switching power supply 10 that may be incorporated into a package according to the present invention. Power supply 10 receives input power provided between an input voltage terminal Vin and ground terminal GND, and generates an output power supply at a different voltage level between an output terminal Vout and the ground terminal GND. Power supply 10 comprises a step-down topology, also known as a bulk converter, wherein the output voltage is less than the input voltage. However, packages according to the present invention can support any type of converter topology, including boost, buck-boost, forward, fly-back, Cuk, etc. Power supply 10 comprises input capacitor 20 coupled between the Vin and GND terminals, a switching regulator circuit 30 coupled between input capacitor 20 and a switch terminal SW, an inductor 40 coupled between the SW and Vout terminals, and an output capacitor 50 coupled between the Vout and GND terminals. In exemplary implementations of packages according to the present invention, capacitor 20 may be implemented by a surface-mount capacitor 120, regulator circuit 30 may be implemented by a semiconductor die 130, inductor 40 may be implemented by a surface-mount inductor 140, and output capacitor 50 may be implemented by a surface-mount capacitor 150. For reference, these components are illustrated in FIG. 1.

Regulator circuit 30 has five terminals as follows: an input voltage terminal VIN coupled to input capacitor 20, and output switch terminal SW coupled to inductor 40 and supply 10's switch terminal SW, a ground terminal GND coupled to supply 10's ground terminal GND, an input enable terminal EN for receiving a digital input signal that instructs circuit 30 to operate, an input feedback terminal FB coupled to output capacitor 50 at terminal Vout. With the enable signal active at terminal EN, regulator circuit 30 switches the leftmost terminal of inductor 40 between the input voltage (at input capacitor 20) and ground in a repeating switching cycle. Inductor 40 is charged by the input voltage input during the first part of the cycle, and discharged to ground during the second part of the cycle. Regulator circuit 30 may comprise a power MOSFET device (shown in dashed lines) to couple inductor 40 to the input voltage during the cycle's first part, and a freewheeling rectifier (shown in dashed lines) to couple inductor 40 to ground during the cycle's second part. Regulator circuit 30 monitors the output voltage provided at its input feedback terminal FB, and adjusts the timing parameters of switching cycle to regulate the output voltage Vout to a target value. For example, the duration of the cycle's first part may be increased to raise a low output voltage level to the target value, and may be decreased to decrease a high output voltage level to the target value. For buck converter applications, circuit 30 may comprise the semiconductor die of FAN5350 3 MHz 600 mA DC/DC Buck Converter, manufactured by Fairchild Semiconductor Corporation, the datasheet of which is incorporated herein by reference. This die comprises the power switching devices and control circuitry integrated together. Nonetheless, it may be appreciated that any semiconductor die may be used in making and using semiconductor die packages according to the present invention.

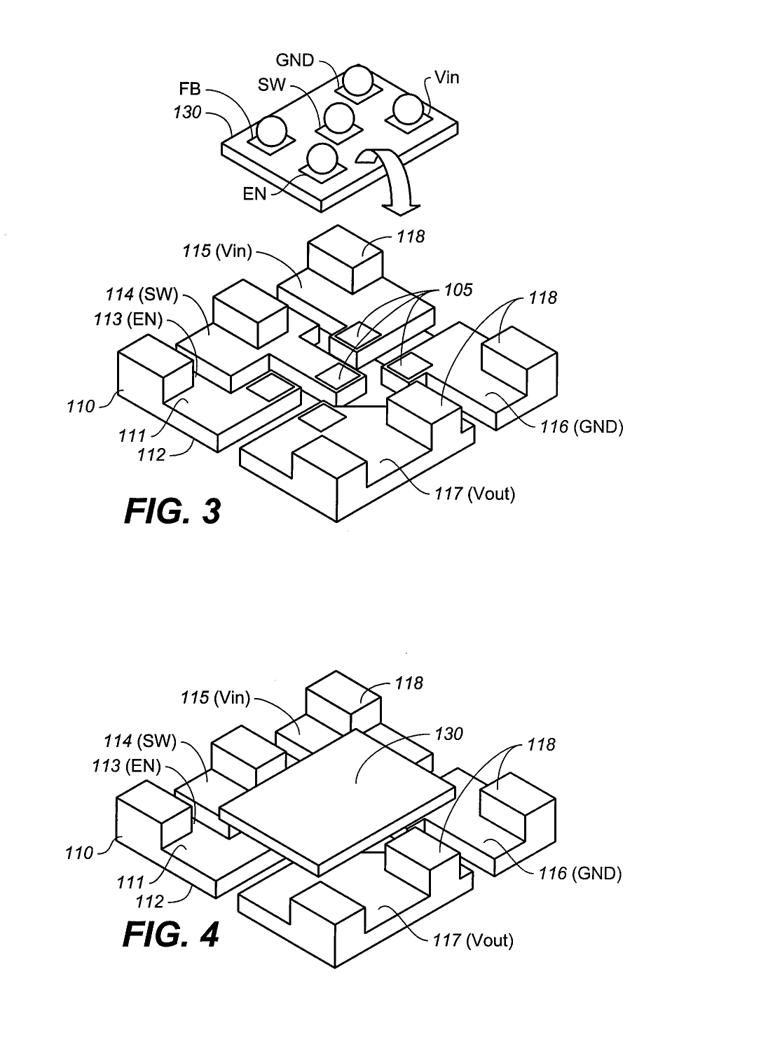

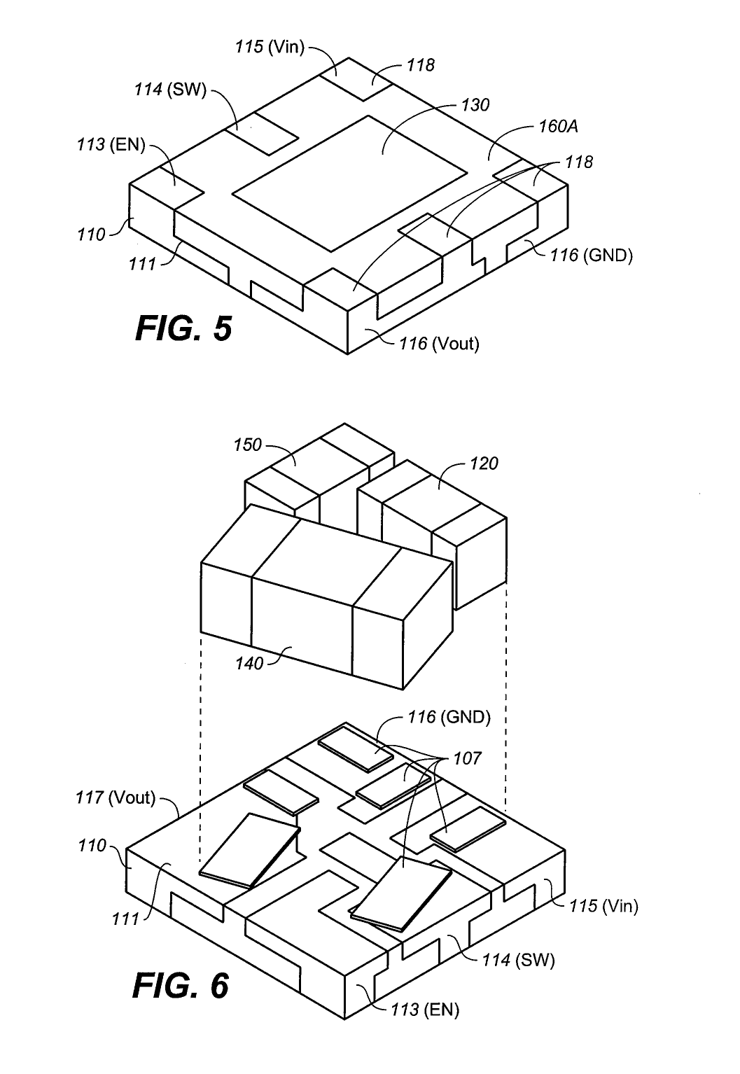

FIG. 2 shows a top perspective view of an exemplary package 100 according to the present invention. Package 100 comprises a leadframe 110 with semiconductor die 130 (shown in FIG. 3), capacitors 120 and 150 (shown in FIG. 6), and inductor 140 assembled thereon as described below in greater detail. Leadframe 110 has a top surface 111, a bottom surface 112, and a plurality of conductive regions 113-117 (region 116 is shown in FIG. 3). The leadframe's top surface 111 faces the bottom of package 100, and the leadframe's bottom surface 112 faces the top of package 100. Semiconductor die 130 is assembled onto the leadframe's top surface 111. Capacitors 120, 150 and inductor 140, which are passive electrical components, are assembled onto the leadframe's bottom surface 112. An electrically insulating material 160A, 160B is disposed about leadframe 110 and the components assembled thereon to form a package. As described in greater detail below, the electrically insulating material 160A, 160B may be disposed in two stages, one for each surface of leadframe 110, or may be disposed in a single stage. The top portion of inductor 140 may be left exposed by material 160B to enable the direct coupling of an electrically insulated heat sink for enhanced cooling. A typical footprint of package 100 is 2.2 mm by 2.2 mm, which is more than 46% smaller than the typical footprint of 3 mm by 3 mm needed by an optimal discrete component implementation. A typical thickness of package 100 is about 1 mm. While this is larger than the thickness of about 0.6 mm for the discrete components, most product applications have ample vertical space and can accommodate it without difficulty.

FIGS. 3-7 illustrate an exemplary method of making package 100. Referring to FIG. 3, leadframe 110 comprises five conductive regions 113-117 disposed between its surfaces 111 and 112, each of which has at least one raised portion 118 that will provide an external connection point to the conductive regions after insulating material 160A is disposed on the leadframe. Raised portions 118 may be formed by conventional leadframe manufacturing processes, such as stamping and etching. Conductive regions 113-117 may be held in place by a frame that surrounds the conductive regions, which is usually made of the same material as the conductive regions, and which is later separated from the regions. Conductive region 113 receives the input enable signal EN for power supply 10, conductive region 114 provides the switch terminal SW of the power supply, conductive region 115 receives the input voltage Vin, conductive region 116 receives the ground GND, and conductive region 117 provides the output voltage Vout of the power supply. Each of the conductive regions has a portion disposed at the center of the leadframe to provide a connection point to semiconductor die 130. Bodies 105 of electrically conductive adhesive material are disposed on the connection points. Bodies 105 may comprise solder paste or a conductive polymeric adhesive, and may be disposed by screening. Semiconductor die 130 is placed onto the middle of leadframe 110 with its five connection pads electrically coupled to corresponding ones of the aforementioned connection points of the leadframe. (Terminals EN, SW, GND, and Vin of die 130 are electrically coupled to the leadframe's conductive regions 113-116, respectively, and the feedback terminal FB is electrically coupled to conductive region 117 to receive the output voltage.) Bodies 105 of conductive adhesive material are thereafter reflowed (in the case of solder) or otherwise cured (in the case of polymeric adhesive) to complete the assembly of die 130 onto leadframe 110. The result of this assembly action is shown in FIG. 4. Typically, the height of raised portions 118 is even with, or lies above, the height of the assembled semiconductor die 130. Leadframe 110 may have a thin backing sheet adhered to its bottom surface 112 to maintain the dimensional stability of the conductive regions during the above assembly action.

Referring to FIG. 5, electrically insulating material 160A may next be disposed around semiconductor die 130 and over top surface 111 of leadframe 110. A simple molding operation may be used for this. The back surface of semiconductor die 130 may be left exposed to facilitate heat conduction to a substrate to which the finished package is to be attached. If present, the thin backing sheet adhered to the bottom surface 112 of leadframe 110 keeps material 160A from flowing to the leadframe's bottom surface 112. If not present, other well-known techniques may be used to prevent material 160A from contacting bottom surface 112. In another method embodiment, material 160A may be disposed in a subsequent step along with material 160B, which may comprise the same material or a different material.

Referring to FIG. 6, bodies 107 of electrically conductive adhesive material are disposed on conductive regions 114-117 at the leadframe's bottom surface 112, and the surface-mount components 120, 140, and 150 are placed onto appropriate ones of the conductive regions. If present, the thin backing sheet adhered to the bottom surface 112 of leadframe 110 is removed prior to this assembly action. Bodies 107 may comprise solder paste or a conductive polymeric adhesive, and may be disposed by screening. Components 120, 140, and 150 may be assembled by conventional surface mounting equipment and methods. Each of components 120, 140, and 150 may have a generally box or cylindrical shape, with two conduction terminals at its distal ends. Input capacitor 120 will have its conduction terminals electrically coupled to conductive regions 115 and 116, respectively, output capacitor 150 will have its conduction terminals electrically coupled to conductive regions 116 and 117, respectively, and inductor 140 will have its conduction terminals electrically coupled to conductive regions 114 and 117, respectively. Bodies 107 of conductive adhesive material may thereafter be reflowed (in the case of solder) or otherwise cured (in the case of polymeric adhesive) to complete the assembly of components 120, 140, and 150 onto leadframe 110. The resulting assembly is shown in FIG. 7.

Referring back to FIG. 2, electrically insulating material 160B may next be disposed over components 120, 140, and 150 and bottom surface 112 of leadframe 110. A simple molding operation may be used for this. If electrically insulating material 160A has not yet been disposed, it may be disposed along with material 160B. Leadframe 110 is then separated from the frame (if present), and any flash material may be trimmed from package 100.

As can be seen in FIGS. 2 and 7, semiconductor die package 100 comprises a rectangular footprint having four sides, and inductor 140 has an axis of symmetry 141 passing through its conduction terminals. In this embodiment, inductor 140 is disposed such that its axis of symmetry 141 forms an angle θ of between 5 degrees and 85 degrees with at least one side of the package's footprint, as shown in FIG. 7. (Actually, an angle θ is formed with respect to two sides, and an angle of 90-θ, with respect to the other two sides, where 90-θ is also between 5 degrees and 85 degrees.) In many implementations, the angled placement enables the electrical component to be coupled to a wider range of arrangements of conductive regions 113-117, and often enables the size of the package's footprint to be reduced. In contrast, each of capacitors 120 and 150 are disposed such that their axes of symmetry are substantially parallel to two sides of the footprint (within 5 degrees), and substantially perpendicular to two other sides of the footprint (85 to 90 degrees). In general, the electrical components may be placed in any combination of parallel and angled placements.

While the above manufacturing method has been illustrated with die 130 being assembled with leadframe 110 before components 120, 140, and 150, it may be appreciated that the method may be practiced with components 120, 140, and 150 being assembled with leadframe 110 before die 130 is assembled with leadframe 110. Also, a non-volatile solder paste (e.g., a solder paste that substantially does not emit gas upon reflow and does not require cleaning after reflow) may be used for bodies 105 and 107 of electrically conductive adhesive material. In this case, it is possible to dispose electrically insulating material 160A on leadframe 110 substantially simultaneously with the assembly of semiconductor dice 130 to the leadframe, and to dispose electrically insulating material 160B on leadframe 110 substantially simultaneously with the assembly of components 120, 140, and 150 onto the leadframe. As one example, semiconductor die 130 may be placed onto leadframe 110, with bodies 105 comprising non-volatile solder paste, a mold may be placed over the die and the leadframe, material 160A may be disposed in the mold, and heat may be applied to simultaneously reflow bodies 105 and solidify/cure material 160A. Similarly, components 120, 140, and 150 may be placed onto leadframe 110, with bodies 107 comprising non-volatile solder paste, a mold may be placed over the components and the leadframe, material 160B may be disposed in the mold, and heat may be applied to simultaneously reflow bodies 107 and solidify/cure material 160B. As another example, semiconductor die 130 may initially be embedded into a block of material 160A with its active surface exposed for contact to leadframe 110, and with material 160A comprising a thermoplastic or partially cured polymeric material. The embedded die may then be placed over and aligned to leadframe 110 with heat applied from the other side of the leadframe to reflow bodies 105 of non-volatile solder paste and to cause material 160A to flow onto and adhere to leadframe 110. Similarly, components 120, 140, and 150 may initially be embedded into a block of material 160B with their surfaces exposed for contact to leadframe 110, and with material 160B comprising a thermoplastic or partially cured polymeric material. The embedded components may then be placed over and aligned to leadframe 110 with heat applied from the other side of the leadframe to reflow bodies 107 of non-volatile solder paste and to cause material 160B to flow onto and adhere to leadframe 110. Further, it is possible that blocks of materials 160A and 160B, with components embedded therein, may be simultaneously assembled onto respective surfaces of leadframe 110 simultaneously (without any thin backing layer attached to leadframe 110), thereby enabling all of components 120-150 to be assembled with leadframe 110 simultaneously.

Accordingly, it should be understood that where the performance of an action of any of the methods disclosed herein is not predicated on the completion of another action, the actions may be performed in any time sequence (e.g., time order) with respect to one another, including simultaneous performance and interleaved performance of various actions. (Interleaved performance may, for example, occur when parts of two or more actions are performed in a mixed fashion.) Accordingly, it may be appreciated that, while the method claims of the present application recite sets of actions, the method claims are not limited to the order of the actions listed in the claim language, but instead cover all of the above possible orderings, including simultaneous and interleaving performance of actions and other possible orderings not explicitly described above, unless otherwise specified by the claim language (such as by explicitly stating that one action proceeds or follows another action).

As noted above, package 100 provides substantial space savings over discrete component implementations. This advantage applies to other embodiments described below. As additional advantages of the packages disclosed herein, the leadframe provides reduced series resistance among the components of the power supply, and the combination of the leadframe with insulating material 160A, 160B provides more reliable electrical connections. In addition, since the packages disclosed herein provide complete functioning circuits, the packages may be tested before being assembled onto product substrates, thereby increasing yields of the product substrates. In addition, as to power supply implementations of the packages of the present invention, the configuration of the power supply components in the packages can provide conversion efficiencies of 90% or more.

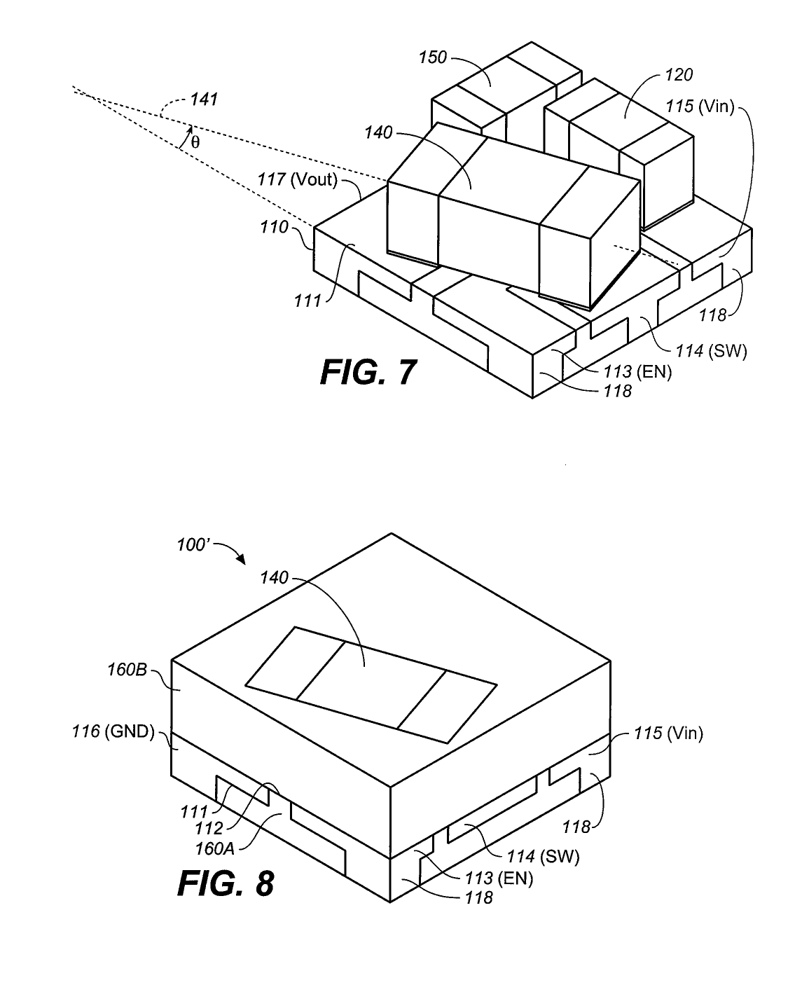

Package 100 has six interconnection terminals provided by the six raised portions 18 shown in FIGS. 2-7. In most applications, access to the signal at terminal SW is not needed, and the corresponding raised portion 18 may be omitted. Also, many applications only need one interconnect terminal for the output voltage Vout, and one of the two raised portions 18 for Vout may also be omitted from the package. FIG. 8 shows a second exemplary semiconductor die package 100′ according to the invention. Package 100′ has substantially the same construction as package 100 except that the raised portion 18 for SW has been omitted, and the center raised portion 18 for Vout has been omitted. Package 100′ may be manufactured using the same methods for manufacturing package 100.

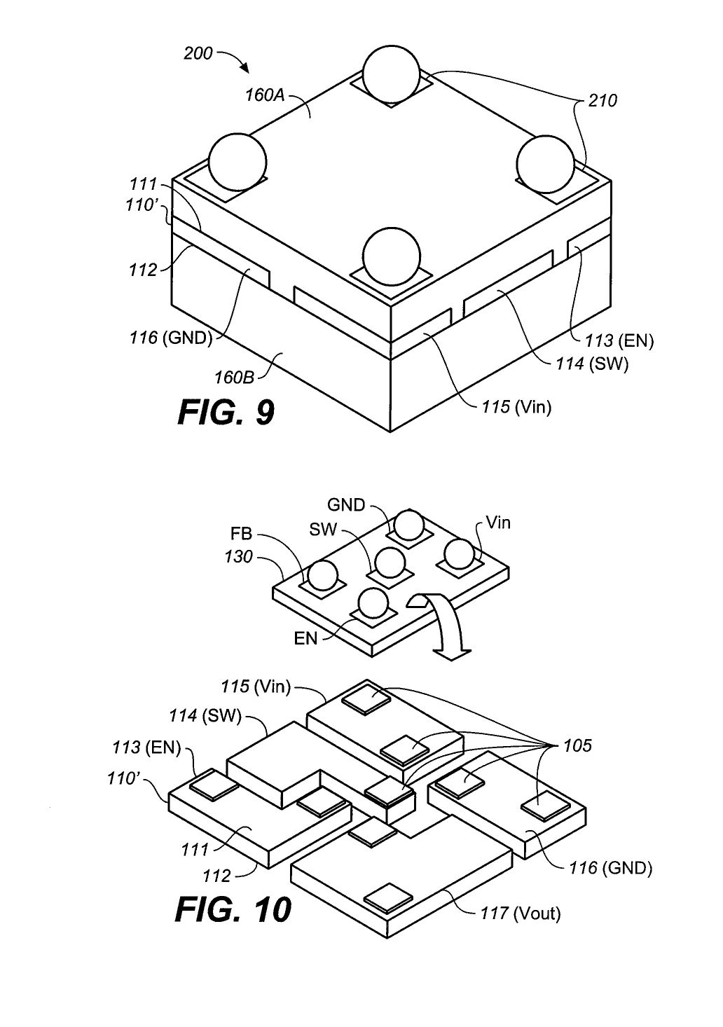

FIG. 9 shows a perspective view of a third exemplary package 200 according to the present invention. Package 200 is similar to package 100 except that raised portions 18 are replaced by conductive members 210 that are attached to the leadframe. This allows material 160A to fully encase semiconductor die 130, as shown in the figure, in the case that it is desirable to provide electrical insulation around die 130. While the height of raised portions 18 can be increased to achieve the same effect, the raised height increases the production cost of leadframe 110, and package 200 can provide a lower cost of manufacturing. Package 200 comprises a leadframe 110′ that has the surfaces 111 and 112 and conductive regions 113-117 of leadframe 110, but does not have raised portions 18. As before, semiconductor die 130, capacitors 120 and 150, and inductor 140 are assembled onto leadframe 110′ as described below in greater detail. A typical footprint of package 200 is 2.2 mm by 2.2 mm, which is more than 46% smaller than the typical footprint of 3 mm by 3 mm needed by an optimal discrete component implementation. A typical thickness of package 200 is about 1.2 mm. While this is larger than the thickness of about 0.6 mm for the discrete components, most product applications have ample vertical space and can accommodate it without difficulty.

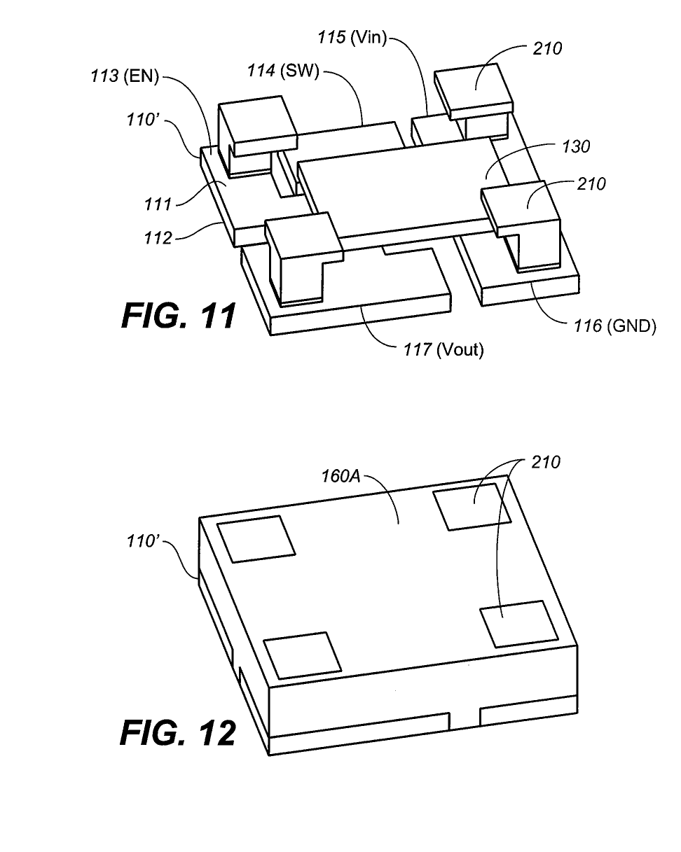

FIGS. 10-12, in combination with references to prior FIGS. 6-7, illustrate an exemplary method of making package 200. Referring to FIG. 10, each of conductive regions 113-117 has a portion disposed at the center of the leadframe to provide a connection point to semiconductor die 130. Bodies 105 of electrically conductive adhesive material are disposed on these connection points, as well as on the outer corner portions of regions 113, 115-117 where conductive members 210 will be electrically coupled. Bodies 105 may comprise solder paste or a conductive polymeric adhesive, and may be disposed by screening. Semiconductor die 130 is assembled onto the middle of leadframe 110 with its five connection pads electrically coupled to corresponding ones of the aforementioned connection points of the leadframe. (As before, terminals EN, SW, GND, and Vin of die 130 are electrically coupled to the leadframe's conductive regions 113-116, respectively, and the feedback terminal FB is electrically coupled to conductive region 117 to receive the output voltage.) Referring next to FIG. 11, conductive members 210 are assembled onto leadframe 110′. Bodies 105 of conductive adhesive material are thereafter reflowed (in the case of solder) or otherwise cured (in the case of polymeric adhesive). The result of this assembly action is shown in FIG. 11. Conductive members 210 may be assembled onto the leadframe before, with, or after the assembly of semiconductor die 130. A placement jig, which may take the form of a temporary holding sheet, may be designed to simultaneously assemble members 210 and die 130 onto leadframe 110′.

As before, conductive regions 113-117 may be held in place by a frame that surrounds the conductive regions, which is usually made of the same material as the conductive regions, and which is later separated from the regions. Leadframe 110′ may have a thin backing sheet adhered to its bottom surface 112 to maintain the dimensional stability of the conductive regions during the above assembly action.

Referring to FIG. 12, electrically insulating material 160A may next be disposed around the sides of conductive members 210 and over semiconductor die 130 and top surface 111 of leadframe 110′. The ends of conductive members 210 are left exposed, and will serve as connection points to package 200. A simple molding operation may be used for this. If present, the thin backing sheet adhered to the bottom surface 112 of leadframe 110′ keeps material 160A from flowing to the leadframe's bottom surface 112. If not present, other well known techniques may be used to prevent material 160A from contacting bottom surface 112. In another method embodiment, material 160A may be disposed in a subsequent step along with material 160B, which may comprise the same material or a different material.

As with methods of making package 100, a non-volatile solder paste may be used for bodies 105 of electrically conductive adhesive material. In this case, it is possible to dispose electrically insulating material 160A on leadframe 110 substantially simultaneously with the assembly of semiconductor dice 130 and conductive members 210 to the leadframe. As one example, semiconductor die 130 and conductive members 210 may be placed onto leadframe 110, with bodies 105 comprising non-volatile solder paste, a mold may be placed over the placed components, material 160A may be disposed in the mold, and heat may be applied to simultaneously reflow bodies 105 and solidify/cure material 160A. As another example, die 130 and conductive members 210 may initially be embedded into a block of material 160A with their surfaces exposed for contact to leadframe 110′, and with material 160A comprising a thermoplastic or partially cured polymeric material. The embedded components may then be placed over and aligned to leadframe 110′ with heat applied from the other side of the leadframe to reflow bodies 105 of non-volatile solder paste and to cause material 160A to flow onto and adhere to leadframe 110′.

Similar to the manufacture of package 100 shown in FIG. 6, bodies 107 of electrically conductive adhesive material are disposed on conductive regions 114-117 at the bottom surface 112 of leadframe 110′, and the surface-mount components 120, 140, and 150 are placed onto appropriate ones of the conductive regions. If present, the thin backing sheet adhered to the bottom surface 112 of leadframe 110′ is removed prior to this assembly action. As before, bodies 107 may comprise solder paste or a conductive polymeric adhesive, and may be disposed by screening, and components 120, 140, and 150 may be assembled by conventional surface mounting equipment and methods. Bodies 107 of conductive adhesive material may thereafter be reflowed (in the case of solder) or otherwise cured (in the case of polymeric adhesive). The resulting assembly is similar to that shown in FIG. 7 for package 100.

Referring back to FIG. 9, electrically insulating material 160B may next be disposed over components 120, 140, and 150 and bottom surface 112 of leadframe 110′. A simple molding operation may be used for this. If electrically insulating material 160A has not yet been disposed, it may be disposed along with material 160B. Leadframe 110′ is then separated from the frame (if present), and any flash material may be trimmed from package 200.

While the above manufacturing method for package 200 has been illustrated with die 130 and conductive members 210 being assembled with leadframe 110′ before components 120, 140, and 150, it may be appreciated that the method may be practiced with components 120, 140, and 150 being assembled with leadframe 110′ before die 130 and conductive members 210 are assembled with leadframe 110′. Also, a non-volatile solder may be used for bodies 105 and 107 of electrically conductive adhesive material, and material 160B may be disposed on leadframe 110′ substantially simultaneously with the assembly of components 120, 140, and 150 onto the leadframe 110′, in similar manners as described above for package 100. Moreover, as described above for the manufacture of package 100, it is possible that blocks of materials 160A and 160B, with components embedded therein, may be simultaneously assembled onto respective surfaces of leadframe 110′ simultaneously (without any thin backing layer attached to leadframe 110′), thereby enabling all of components 120-150 and 210 to be assembled with leadframe 110′ simultaneously. A plurality of solder balls may or may not placed on the exposed surfaces of the conductive members 210 (FIG. 9), or on the exposed surface of raised portions 118 of the conductive regions 113-117 regions at the bottom of packages 100 and 100′ (FIGS. 2 and 8).

While the above packages have been illustrated with the use of one semiconductor die, it may be appreciated that further embodiments may include two or more semiconductor die, which may be assembled onto either of the leadframe surface 111 or 112. In addition, while the above packages have been illustrated with the passive components (120, 140, and 150) being assembled onto the leadframe's bottom surface 112, further embodiments may include passive components mounted on the leadframe's top surface 111.

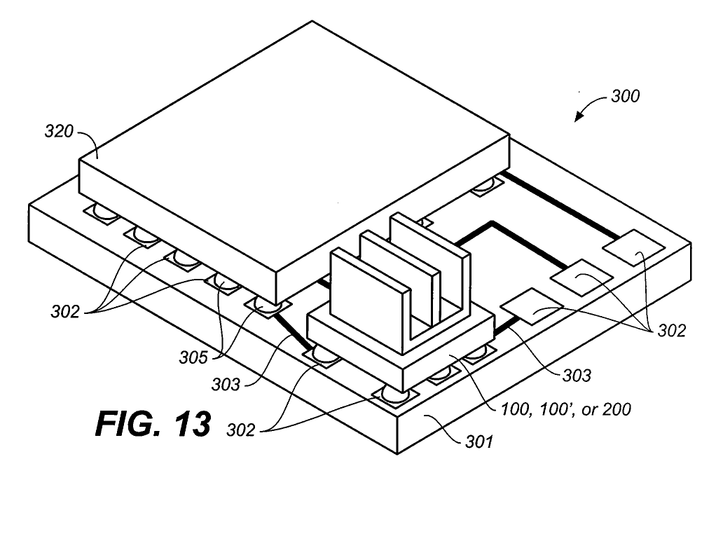

FIG. 13 shows a perspective view of a system 300 that comprises semiconductor package 100, 100′, or 200 according to the present invention. System 300 comprises an interconnect substrate 301, a plurality of interconnect pads 302 to which components are attached, a plurality of interconnect traces 303 (only a few of which are shown for the sake of visual clarity), an instance of a package according to the invention, a second package 320, and a plurality of solder bumps 305 that interconnect the packages to the interconnect pads 302. A miniature, electrically insulated heat sink 310 may be attached to package 100, 100′, or 200.

The semiconductor die packages described above can be used in electrical assemblies including circuit boards with the packages mounted thereon. They may also be used in systems such as phones, computers, etc.

Some of the examples described above are directed to “leadless” type packages such as MLP-type packages (microleadframe packages) where the terminal ends of the leads do not extend past the lateral edges of the molding material. Embodiments of the invention may also include leaded packages where the leads extend past the lateral surfaces of the molding material.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly described with respect to the illustrated embodiments, it will be appreciated that various alterations, modifications, adaptations, and equivalent arrangements may be made based on the present disclosure, and are intended to be within the scope of the invention and the appended claims.

What is claimed is:

1. A semiconductor die package comprising:
a leadframe having a first surface, a second surface, and a plurality of conductive regions disposed between the first and second surfaces;
at least one semiconductor die disposed on the first surface of the leadframe and electrically coupled to at least one conductive region of the leadframe; and
at least one passive electrical component disposed on the second surface of the leadframe and electrically coupled to at least one conductive region of the leadframe.

2. The semiconductor die package of claim 1, wherein the at least one semiconductor die has a first conductive region electrically coupled to a first conductive region of the leadframe, and wherein the at least one passive component has a first conductive region electrically coupled to the first conductive region of the leadframe.

3. The semiconductor die package of claim 1, wherein the at least one passive electrical component comprises an inductor.

4. The semiconductor die package of claim 3, further comprising a body of electrically insulating material disposed over the second surface of the leadframe and at least around a portion of the inductor.

5. The semiconductor die package of claim 4, wherein the inductor has a box shape with a top surface, a bottom surface facing the leadframe, and a plurality of side surfaces, and where at least a major portion of the inductor's top surface is left exposed by the body of electrically insulating material.

6. The semiconductor die package of claim 3, wherein the inductor has a second conductive region electrically coupled to a second conductive region of the leadframe, and wherein the semiconductor die package further comprises a capacitor disposed on the second surface of the leadframe, the capacitor having a first electrically conductive region electrically coupled to the second conductive region of the leadframe and a second electrically conductive region electrically coupled to a third conductive region of the leadframe.

7. The semiconductor die package of claim 6, wherein the at least one semiconductor die has a second conductive region electrically coupled to a fourth conductive region of the leadframe, wherein the semiconductor die package further comprises a second capacitor disposed on the second surface of the leadframe, the second capacitor having a first electrically conductive region electrically coupled to the fourth conductive region of the leadframe and a second electrically conductive region electrically coupled to a conductive region of the leadframe.

8. The semiconductor die package of claim 6, wherein the at least one semiconductor die, inductor, and capacitor are configured to provide a boost-converter power supply.

9. The semiconductor die package of claim 3 wherein the package further comprises a rectangular footprint having four sides, wherein the inductor has two conduction terminals and an axis of symmetry passing through its conduction terminals, and wherein the inductor is disposed such that its axis of symmetry and at least one side of the package's footprint are at an angle of between 5 degrees and 85 degrees.

10. The semiconductor die package of claim 1 wherein the package further comprises a rectangular footprint having four sides, wherein the at least one passive electrical component has two conduction terminals and an axis of symmetry passing through its conduction terminals, and wherein the at least one passive electrical component is disposed such that its axis of symmetry and at least one side of the package's footprint are at an angle of between 5 degrees and 85 degrees.

11. The semiconductor die package of claim 1, wherein the at least one semiconductor die has a top surface, a bottom surface facing the leadframe, and a plurality of sides, and wherein the semiconductor die package further comprises a body of electrically insulating material disposed over the first surface of the leadframe and at least around the sides of the at least one semiconductor die.

12. The semiconductor die package of claim 11, wherein at least a major portion of the top surface of the at least one semiconductor die is left exposed by the body of electrically insulating material.

13. The semiconductor die package of claim 1 wherein the leadframe comprises a plurality of raised portions disposed on the leadframe's first surface and electrically coupled to the leadframe's conductive regions.

14. The semiconductor die package of claim 13 wherein each raised portion has a top surface, a bottom surface facing the leadframe, and one or more side surfaces between its top and bottom surfaces, and wherein the semiconductor die package further comprises a body of electrically insulating material disposed over the first surface of the leadframe and at least around a portion of each raised portion, and with at least a major portion of the top surface of each raised portion being left exposed by the body of electrically insulating material.

15. The semiconductor die package of claim 1 wherein the leadframe comprises a plurality of conductive members disposed on the leadframe's first surface and electrically coupled to the leadframe's conductive regions.

16. The semiconductor die package of claim 15 wherein each conductive member has a top surface, a bottom surface facing the leadframe, and one or more side surfaces between its top and bottom surfaces, and wherein the semiconductor die package further comprises a body of electrically insulating material disposed over the first surface of the leadframe and at least around a portion of each conductive member, and with at least a major portion of the top surface of each conductive member being left exposed by the body of electrically insulating material.

17. A system comprising an interconnect substrate and the semiconductor die package of claim 1 attached to the interconnect substrate.

18. A method of manufacturing a semiconductor die package, the method comprising:
assembling at least one semiconductor die and a leadframe together at a first surface of the leadframe and with a conductive region of the die electrically coupled to at least one conductive region of the leadframe; and
assembling at least one passive electrical component and the leadframe together at a second surface of the leadframe and with a conductive region of the die electrically coupled to at least one conductive region of the leadframe.

19. The method of claim 18 wherein the at least one passive electrical component and the leadframe are assembled together before the at least one semiconductor die and the leadframe are assembled together.

20. The method of claim 18 wherein the at least one semiconductor die and the leadframe are assembled together before the at least one passive electrical component and the leadframe are assembled together.

21. The method of claim 18 further comprising assembling a plurality of conductive members and the leadframe together at the leadframe's first surface and with each conductive member being electrically coupled to a conductive region of the leadframe.

22. The method of claim 18 wherein the at least one semiconductor die has a top surface, a bottom surface facing the leadframe, and a plurality of sides, and wherein the method further comprises disposing a body of electrically insulating material over the first surface of the leadframe and at least around the sides of the at least one semiconductor die.

23. The method of claim 18 further comprising disposing a body of electrically insulating material over the second surface of the leadframe and at least around a portion of the at least one passive electrical component.

24. A method of manufacturing a semiconductor die package, the method comprising:
assembling at least one semiconductor die and a leadframe together at a first surface of the leadframe and with a conductive region of the die electrically coupled to at least one conductive region of the leadframe, the at least one semiconductor die having a top surface, a bottom surface facing the leadframe, and a plurality of sides;
thereafter disposing a body of electrically insulating material over the first surface of the leadframe and at least around the sides of the at least one semiconductor die; and
thereafter assembling at least one passive electrical component and the leadframe together at a second surface of the leadframe and with a conductive region of the die electrically coupled to at least one conductive region of the leadframe.

25. The method of claim 24 further comprising:
assembling, prior to disposing the body of electrically insulating material, a plurality of conductive members and the leadframe together at the leadframe's first surface and with each conductive member being electrically coupled to a conductive region of the leadframe.

26. The method of claim 25 wherein the conductive members are assembled with the leadframe substantially simultaneously with the assembly of the at least one semiconductor die and the leadframe.

27. The method of claim 25 wherein the conductive members are assembled with the leadframe after the assembly of the at least one semiconductor die and the leadframe.
